(19) United States
(12) Patent Application Publication
(10) Pub. No.: US 2020/0176515 A1
(43) Pub. Date: Jun. 4, 2020

(54) DISPLAY PANEL AND DISPLAY DEVICE

(71) Applicant: WUHAN CHINA STAR OPTOELECTRONICS TECHNOLOGY CO., LTD., Wuhan, Hubei (CN)

(72) Inventors: Chaoqun YANG, Wuhan, Hubei (CN); Changchih HUANG, Wuhan, Hubei (CN)

(21) Appl. No.: 16/334,378

(22) PCT Filed: Jan. 8, 2019
(86) PCT No.: PCT/CN2019/070728

§ 371 Date: Mar. 19, 2019

(30) Foreign Application Priority Data
Nov. 29, 2018 (CN) 201811446802.X

(51) Int. Cl. H01L 27/32; H01L 33/50; H01L 51/52; G02F 1/1335

(52) U.S. Cl. CPC H01L 27/322; H01L 33/502; G02F 2202/36; G02F 1/133514; G02F 1/133617; H01L 51/5281

(57) ABSTRACT

The present disclosure provides a display panel and display device. The display panel includes a substrate and a color film layer formed on the substrate. A plurality of first color resistances are formed in the color film layer, a plurality of green or red quantum dots are formed in the first color resistances. A first shielding layer is formed on the first color resistances, and the first shielding layer is made of yellow photoresistance material or red photoresistance material. The present disclosure provides a display panel and display device to improve color purity of green light or red light emitted by the quantum dots excited in the color resistance.

### CROSS REFERENCE TO RELATED APPLICATION

This application claims the priority of International Application No. PCT/CN2019/070728, filed on 2019 Jan. 8, which claims priority to Chinese Application No. 201811446802.X, filed on 2018 Nov. 29. The entire disclosures of each of the above applications are incorporated herein by reference.

### BACKGROUND OF INVENTION

### Field of Invention

The present invention relates to a display field, and particularly to a display panel configured for display devices of organic light emitting diode (OLED), liquid crystal display (LCD) et al.

### Description of Prior Art

As the user experience of display panels in the market continuously improves, display devices with higher color gamut and higher brightness are being developed and manufactured and have become a goal of various panel manufacturers in the industry. Thin film transistor-liquid crystal display (TFT-LCD) panels face a risk of being phased out by the strongly developed organic light emitting diode (OLED) technique. It is time for the panel manufacturers to think about the most urgent point, that how to enhance their competitiveness and occupy a position in the market.

Because quantum dots (QDs) materials have wide absorption peaks and narrow emission peaks to make higher purity in color display, they are applied to the display devices to improve the display effects. For example, they are applied to the LCD to continue using the process for manufacturing the LCD and to effectively improve the color gamut of the LCD, thereby enhancing the competitiveness of the LCD panel and making it as a key technique to contend with the OLED.

At present, the panel manufacturers, such as Samsung, BOE Technology Group, AMO, and China Star Optoelectronics Technology (CSOT) are vigorously developing QD technology. However, QD's own limitations and high-specification targets have made it difficult to implement. It is difficult to achieve BT2020 color gamut more than 90%, because it is more difficult to improve quantum yield (QY) from the perspective of QD materials and to reduce full width at half maximum (FWHM).

Therefore, it is necessary to develop a new display panel to overcome the defects in prior technique.

### SUMMARY OF INVENTION

The application mainly provides a display panel to improve a color purity of green light or red light of quantum dots in color resistance been excited and then emitting.

The present disclosure employs the following technical schemes.

A display panel includes a substrate, wherein a color film layer is formed on the substrate, a plurality of first color resistances are formed in the color film layer, a plurality of green or red quantum dots are formed in the first color resistances, a first shielding layer is formed on the first color resistances, and the first shielding layer is made of yellow photoresist material or red photoresist material.

Further, in one embodiment, the quantum dots formed in the first color resistances are green quantum dots, the first shielding layer is made of yellow photoresist material.

Further, in one embodiment, a thickness of the yellow first shielding layer is 1-6 μm.

Further, in one embodiment, the quantum dots formed in the first color resistances are green quantum dots, and the first shielding layer is a bilayer structure and includes a first yellow film layer made of yellow photoresist material and a second green film layer made of green photoresist material.

Further, in one embodiment, a thickness of the first yellow film layer is 0.5-3 μm, a thickness of the second green film layer is 2-7 μm.

Further, in one embodiment, the quantum dots formed in the first color resistances are green quantum dots, and the first shielding layer is made of yellow photoresist material containing green material.

Further, in one embodiment, a mass ratio of the green material is 15-85%.

Further, in one embodiment, the quantum dots formed in the first color resistances are red quantum dots, and the first shielding layer is made of red photoresist material.

Further, in one embodiment, a thickness of the red first shielding layer is 1.5-5 μm.

Further, in one embodiment, a red color of the red photoresist material is a red color in digital cinema initiatives (DCI) color system.

Further, in one embodiment, the quantum dots formed in the first color resistances are red quantum dots, the first shielding layer is a bilayer structure includes a first yellow film layer made of yellow photoresist material and a second red film layer made of red photoresist material.

Further, in one embodiment, a thickness of the first yellow film layer is 0.5-3 μm, a thickness of the second red film layer is 1-4 μm.

Further, in one embodiment, a plurality of diffusion particles are added in the first color resistances, and a volume of addition is 0.1%-20% of the amount of the color resistance quantum dots.

Further, in one embodiment, a grain size of the diffusion particles is between 100 nm and 300 nm.

Further, in one embodiment, the a plurality of second color resistances are formed in the color film layer, a second shielding layer is formed on the second color resistances, a plurality of green quantum dots are formed in the first color resistance, a plurality of red quantum dots are formed in the second color resistance.

The present disclosure also provides a display device including the display panel of the present disclosure.

The beneficial effect of this invention is: in the display panel of the application, yellow photoresist materials are applied, additions are added into the yellow photoresist materials, or the yellow photoresist materials are combined with other color photoresist materials to form a new shielding layer to improve a color purity of red light and green color emitted from the color resistance layer.

Further, the diffusion particles are added into the first color resistances to improve a luminance of the quantum dots of the color resistance to effectively solves a problem of luminance attenuation which light emitted by the quantum dots excited in the color resistance layer pass through blue shielding layer or transmit process.

### BRIEF DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 is a schematic view of a display panel of one exemplary embodiment according to the present disclosure.

### DETAILED DESCRIPTION OF PREFERRED EMBODIMENTS

The technical solutions of a display panel and a display device thereof according to the present invention will be further described in detail below with reference to the accompanying drawing and embodiments.

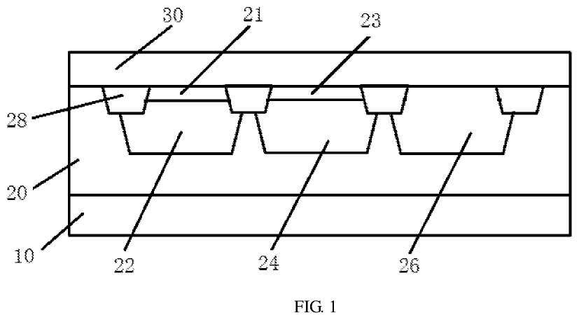

Referring to FIG. 1, the present application provides a display panel, which includes a substrate 10. A color film layer 20 and a glass layer 30 are formed on the substrate 10.

A plurality of first color resistances 22, a plurality of second color resistances 24 and a plurality of third color resistances 26 are formed in the color film layer 20, a plurality of black matrix (BM) layers 28 are formed on an upper part between the color resistances. A plurality of red quantum dots are formed in the first color resistances 22, a plurality of green quantum dots are formed in the second color resistance 24, a plurality of blue quantum dots are formed in the second color resistance 26.

Further, a first shielding layer 21 and a second shielding layer 23 are formed on the first color resistances 22 and the second color resistances 24. The shielding layers are configured for eliminating an extra blue backlight emitted through the color resistances, and because the blue quantum dots are added in the third color resistances 26, there is no need to set the shielding layers to block the extra blue light emitted through the color resistances.

About the material of the first shielding layer 21 and the second shielding layer 23, the present application provides multiple implementation schemes, that are illustrated as follows:

As the red quantum dots in the first color resistance 22 are excited to emits red light, in order to eliminate the influence of extra blue light and to improve the color purity of the red light, the present application reveals a first embodiment for the first shielding layer 21 is: the first shielding layer 21 is made of yellow photoresist material, because of yellow color characteristic can better shield the blue color, thus it can effectively block extra blue light. A thickness of the yellow first shielding layer is less than 6 μm.

A second embodiment for the first shielding layer 21 that the present application is: the first shielding layer 21 is made of red photoresist material, because of a characteristic of red color, so it is better for shielding the blue color, thus it can effectively block extra blue light. Further, a red color of the red photoresist material is a red color in digital cinema initiatives (DCI) color system. A thickness of the red first shielding layer is 1.5-5 μm.

The present application reveals a third embodiment for the first shielding layer 21 is: the first shielding layer is a bilayer structure including a red film layer made of red photoresist material and a yellow film layer made of yellow photoresist material. A thickness of the red film layer is 1.0-4.0 μm, and a thickness of the yellow film layer is 0.5-3.0 μm.

As the green quantum dots in the second color resistance 24 are excited to emits green light, in order to improve the color purity, a first embodiment of the second shielding layer 23 that the present application is: the second shielding layer 23 is made of single yellow photoresistance material, because of a characteristic of yellow color, so it is better for shielding the blue color, thus it can effectively block extra blue light. A thickness of the yellow shielding layer is less 6 μm.

The present application reveals a second embodiment for the second shielding layer 23 is: the second shielding layer is a bilayer structure including a yellow film layer made of yellow photoresist material and a green film layer made of green photoresist material. A thickness of the yellow film layer is 0.5-3.0 μm, and a thickness of the green film layer is 2.0-7.0 μm.

The present application reveals a third embodiment for the second shielding layer 23 is: the second shielding layer is a single layer structure made of the yellow photoresist material, green material is added in the yellow photoresistance material to form a yellow green color, and a mass ratio of the green material is 15-85%. A thickness of the second shielding layer 23 is less than 6 μm.

Further, because all of the shielding layers are made of photoresist material, they are formed on the respective color resistance through a known photoresistance process in the industry, but not limited.

Further, in other embodiments, in order to increase luminance of the quantum dots in each of the color resistance, a plurality of diffusion particles can be added in each color resistance. A grain size of the diffusion particles is 100-300 nm, a volume of the amount of the quantum dots in the color resistance is 0.1%-20%.

In the display panel of the present application, yellow photoresistance materials are applied, additions are added into the yellow photoresistance materials, or the yellow photoresistance materials are combined with other color photoresistance materials to form a new shielding layer to improve color purity of red light and green light emitted from the color resistance layer.

Further, the diffusion particles are added into the first color resistances to improve luminance of the quantum dots of the color resistance to effectively solves a problem of luminance attenuation after light emitted by the quantum dots excited in the color resistance layer passes through a blue shielding layer or is in a process of transmission.

The technical scope of the present invention is not limited to the above description of the contents. Any person who skilled in the art may deform and modify the embodiment of the present invention within the spirit and scope of the appended claims, but these deformation and modification belong to the protection scope of the present invention.

What is claimed is:

1. A display panel, comprising: a substrate, wherein a color film layer is formed on the substrate, a plurality of first color resistances are formed in the color film layer, a plurality of green or red quantum dots are formed in the first color resistances, a first shielding layer is formed on the first color resistances, and the first shielding layer is made of yellow photoresist material or red photoresist material.

2. The display panel of claim 1, wherein the quantum dots formed in the first color resistances are green quantum dots, the first shielding layer is made of yellow photoresist material.

3. The display panel of claim 1, wherein the quantum dots formed in the first color resistances are green quantum dots, and the first shielding layer is a bilayer structure and comprises a first yellow film layer made of yellow photoresist material and a second green film layer made of green photoresist material.

4. The display panel of claim 1, wherein the quantum dots formed in the first color resistances are green quantum dots, and the first shielding layer is made of yellow photoresist material containing green material.

5. The display panel of claim 4, a mass ratio of the green material is 15-85%.

6. The display panel of claim 1, wherein the quantum dots formed in the first color resistances are red quantum dots, and the first shielding layer is made of red photoresist material.

7. The display panel of claim 6, wherein a red color of the red photoresist material is a red color in digital cinema initiatives (DCI) color system.

8. The display panel of claim 1, wherein the quantum dots formed in the first color resistances are red quantum dots, the first shielding layer is a bilayer structure comprises a first yellow film layer made of yellow photoresist material and a second red film layer made of red photoresist material.

9. The display panel of claim 1, wherein a plurality of diffusion particles are added in the first color resistances, and a volume of addition is 0.1%-20% of the amount of the color resistance quantum dots.

10. A display device comprising the display panel of claim 1.
